(19) United States
(12) Patent Application Publication
(10) Pub. No.: US 2008/0150018 A1
(43) Pub. Date: Jun. 26, 2008

(54) Semiconductor device

(75) Inventor: Atsushi Tanabe, Shiga (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/003,175

(22) Filed: Dec. 20, 2007

(30) Foreign Application Priority Data
Dec. 26, 2006 (JP) 2006-350367

(51) Int. Cl. H01L 29/78

(52) U.S. Cl. 257/330; 257/E29.262

(57) ABSTRACT

An object of the present invention is to provide a semiconductor device having an improved reliability and a reduced contact resistance, which is obtained by achieving an increased dimension of the contact area and an improved adhesiveness between the semiconductor layer and the barrier metal without increasing a dimension of the opening of the contact hole as low as possible.

A semiconductor device of the present invention includes a p⁺ type base layer that forms a principal surface, an n⁺ type source layer formed on the p⁺ type base layer, a contact hole that is provided to extend through the n⁺ type source layer, and an electric conductor plug that plugs the inside of the contact hole, wherein a section in the side surface of the n⁺ type source layer exposing to the contact hole includes a taper portion broadening toward the surface of the opening of the contact hole, and an angle between a section in the side surface of the n⁺ type source layer and the principal surface differs from an angle between a section in the side surface of the p⁺ type base layer exposing to the contact hole and the principal surface.

This application is based on Japanese patent application No. 2006-350,367, the content of which is incorporated hereinto by reference.

### BACKGROUND

1. Technical Field

The present invention relates to a semiconductor device, and particularly relates to a semiconductor device including a semiconductor layer formed in a semiconductor substrate and an electric conductor plug that is in contact with a side surface thereof.

2. Related Art

A U-shaped metal oxide semiconductor field effect transistor (UMOSFET), which includes a source layer formed on a surface of a semiconductor substrate an electric conductor plug that couples to the source electrode formed on the semiconductor substrate, is shown in FIGS. 7A and 7B as an example of a conventional semiconductor device. FIG. 7A is a plan view, illustrating an arrangement of a plurality of cells in a UMOSFET, and FIG. 7B is a longitudinal sectional view along line A-A of FIG. 7A.

In FIGS. 7A and 7B, a reference numeral 1 represents an n⁺ type silicon substrate, 2 represents an n⁻ type epitaxial layer, 6 represents a gate trench, 7 represents a gate insulating film, 8 represents a polysilicon layer, 9 represents a p type base layer, 10 represents an n⁺ type source layer, 11 represents an interlayer insulating film, 12 represents a contact hole, 14 represents a p⁺ type base contact layer, 16 represents a barrier metal, 17 represents an electric conductor plug, 18 represents a source electrode, 19 represents a drain electrode, and 20 represents a unit cell.

As shown in FIG. 7A, each of unit cells 20 is separately formed via gate trenches 6, and a contact hole 12 is disposed in the center of each of the unit cells 20.

While an exemplary implementation of the rectangular unit cells 20 arranged in a lattice pattern is shown in reference to FIG. 7A, the cell-arrangement is not limited thereto, and an alternative arrangement of altering positions in line-writing direction may also be employed, and a hex or a round shaped geometry may also be employed for the cell.

As shown in FIG. 7B, a p type base layer 9 is formed on a surface of an n⁻ type epitaxial layer 2 formed on an n⁺ type silicon substrate 1.

Further, an n⁺ type source layer 10 is formed on a surface of the p type base layer 9.

Further, a gate trench 6 is formed so as to extend through the n⁺ type source layer 10 and the p type base layer 9 and reach the n⁻ type epitaxial layer 2, and a polysilicon layer 8 is buried therein via a gate insulating film 7.

An interlayer insulating film 11 is formed on the polysilicon layer 8 that serves as a gate electrode, and a contact hole 12 having a certain depth and extending through the n⁺ type source layer 10 to reach the p type base layer 9 is formed between the adjacent gate trenches 6.

In addition to above, in order to facilitate a formation of a buried structure of the electric conductor plug 17, a tapered angle of a fixed gradient (the tapered angle is determined as an angle between the surface of the substrate and the side surface of the contact hole) may be provided over the whole side surface of the contact hole 12.

Further, a p⁺ type base contact layer 14 is formed under the bottom of the contact hole 12.

A barrier metal 16 composed of titanium nitride (TiN) and extending over the interlayer insulating film 11 is deposited in the contact hole 12.

Further, an electric conductor plug 17 composed of tungsten (W) is formed in the inside of the contact hole 12, and a source electrode 18 is formed on the surface thereof.

In addition, a drain electrode 19 is formed on a back surface of the n⁺ type silicon substrate 1.

In an operation of such UMOSFET as described above, a certain voltage applied to the gate electrode (not shown) causes an inversion of the p type base layer 9 that is opposed to the side surface of the gate trench 6 to create an inverted channel region, generating a drain electric current flows.

An electric current path in ON-state passes through the source electrode 18, the electric conductor plug 17, the barrier metal 16, the n⁺ type source layer 10, the inverted channel region, the n⁻ type epitaxial layer 2, the n⁺ type silicon substrate 1 and the drain electrode 19.

Next, a process for manufacturing the UMOSFET described above will be described in reference to FIGS. 8A and 8B and FIGS. 9C and 9D. FIGS. 8A and 8B and FIGS. 9C and 9D are cross-sectional views of a device, illustrating each operation in the manufacturing process.

First of all, as shown in FIG. 8A, an etching mask composed of a silicon oxide film (not shown), a silicon nitride film and oxide film are formed on the n⁻ type epitaxial layer 2, which has been grown on the n⁺ type silicon substrate 1, and then a silicon etch process is conducted to form the gate trenches 6 in the n⁻ type epitaxial layer 2.

Here, the depth of the gate trench 6 is designed to be smaller than the thickness of the n⁻ type epitaxial layer 2, but larger than the thickness of a p type base layer as will be formed in the later process. In addition, a sacrificial oxide film (not shown) is grown on a silicon surface, and then is etched off to form rounded opening corners and rounded bottom corners of the gate trenches 6.

Then, the gate insulating films 7 are formed on the surface of the n⁻ type epitaxial layer 2 and in the interior of the gate trenches 6 via a thermal oxidation process, and then a polysilicon is deposited via a chemical vapor deposition (CVD) process.

For the purpose of reducing a resistance of polysilicon that serves as the gate electrode, impurity such as phosphorus (P), arsenic (As) and the like may be diffused into polysilicon after the deposition thereof, or the deposition of polysilicon may be conducted while such impurity is doped.

Next, polysilicon is etched back to form polysilicon layers 8 in the interior of the gate trenches 6, and then an ion implantation of boron (B) and a thermal processing are carried out to form a p type base layer 9 that reaches to a depth shallower than the depth of the gate trench 6.

Subsequently, an ion implantation with arsenic (As) and a thermal processing are carried out for a certain region in the surface of the p type base layer 9 to form the n⁺ type source layer 10.

Then, as shown in FIG. 8B, an interlayer insulating film 11 is deposited thereon via a CVD process, and thereafter, a resist mask having a certain pattern (not shown) is formed and the interlayer insulating film 11 is plasma-etched through the formed resist mask, and further, a plasma etching is conducted through the n⁺ type source layer 10 to a depth reaching the p type base layer 9 to form the contact hole 12.

Then, an oxide film 13 is deposited via a CVD process, and then an ion implantation with boron difluoride (BF₂) and a thermal processing are carried out to form a p⁺ type base contact layer 14 under the bottom of the contact hole 12.

Next, such oxide film 13 is removed, and then, as shown in FIG. 9C, a barrier metal 16 composed of titanium nitride (TiN) formed via a sputter process, and then tungsten (W) is deposited via a CVD process and is etched back to form an electric conductor plug 17 in the contact hole 12.

Next, as shown in FIG. 9D, aluminum silicon (AlSi) is deposited thereon via a sputter process, and then a patterning is carried out via a photolithographic process and an etching process to form a source electrode 18.

Thereafter, a desired thickness of the back surface of the n⁺ silicon substrate 1 is removed, and then a vapor deposition process is conducted to form a drain electrode 19 (see, for example, FIG. 1 to FIG. 6 of Japanese Patent Laid-Open No. 2003-318,396).

However, since the conventional UMOSFET as described above is configured to form the contact hole 12 for source contact and the electric conductor plug 17 so as to provide a contact with the n⁺ type source layer 10 in the side surface thereof in order to achieve a cell shrinkage, problems of providing smaller dimension of the contact area and difficulty in providing sufficient adhesiveness between the n⁺ type source layer 10 and the barrier metal 16.

Insufficient adhesiveness between the n⁺ type source layer 10 and the barrier metal 16 may cause an increased contact resistance (on-resistance) or unstable contact resistance (on-resistance) caused by a stresses generated under the condition of the heat cycle.

In addition to above, even if a tapered portion is provided over the whole side surface of the contact hole 12 as described above in consideration of the covering capability, larger taper angle provides poor contribution to an increase in the dimension of the contact area between the n⁺ type source layer 10 and the barrier metal 16 or an improvement in the adhesiveness therebetween. On the other hand, if the tapered angle is simply reduced over the whole side surface thereof, the dimension of the opening of the contact hole 12 remarkably increases, which leads to a reduced distance to the gate trench 6, causing a reduced breakdown voltage between the gate and the source.

### SUMMARY

According to one aspect of the present invention, there is provided a semiconductor device, comprising: a first semiconductor layer having a principal surface; a second semiconductor layer formed on the principal surface; a contact hole provided in the first semiconductor layer so as to extend through the second semiconductor layer; and an electric conductor plug that plugs the contact hole, wherein a section in a side surface of the second semiconductor layer exposed to the contact hole has a tapered portion, which broadens toward an aperture of the contact hole, and wherein a first angle between a section in a side surface of the second semiconductor layer and the principal surface differs from a second angle between a section in a side surface of the first semiconductor layer exposed to the contact hole and the principal surface.

According to the semiconductor device of the present invention, a semiconductor device having an improved reliability and a reduced contact resistance, which is obtained by achieving an increased dimension of the contact area and an improved adhesiveness between the semiconductor layer and the barrier metal without increasing a dimension of the opening of the contact hole as low as possible, is presented.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are a vertical sectional view of, and an enlarged view of a main part of, a UMOSFET presented as an example of a semiconductor device of the present invention, respectively;

FIGS. 2A and 2B are cross-sectional views of a device, illustrating conditions of completing each operation in the process for manufacturing of UMOSFET of the present invention;

FIGS. 3C and 3D are cross-sectional views of the device, illustrating conditions of completing each operation in the process for manufacturing of UMOSFET of the present invention;

FIGS. 4E and 4F are cross-sectional views of the device, illustrating conditions of completing each operation in the process for manufacturing of UMOSFET of the present invention;

FIGS. 5G and 5H are cross-sectional views of the device, illustrating conditions of completing each operation in the process for manufacturing of UMOSFET of the present invention;

FIG. 6I is a cross-sectional view of the device, illustrating a condition of completing an operation in the process for manufacturing of UMOSFET of the present invention;

FIG. 7A and FIG. 7B are a plan view and a longitudinal sectional view along line A-A, illustrating an example of a conventional UMOSFET;

FIGS. 8A and 8B are cross-sectional views of a device, illustrating each operation in the manufacturing process for a conventional UMOSFET; and

FIGS. 9C and 9D are cross-sectional views of the device, illustrating each operation in the manufacturing process for the conventional UMOSFET.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiments illustrated for explanatory purposed.

The present invention achieves the object of the present invention for providing a semiconductor device having an improved reliability and a reduced contact resistance, which is obtained by achieving an increased dimension of the contact area and an improved adhesiveness between the semiconductor layer and the barrier metal without increasing a dimension of the opening of the contact hole as low as possible, by providing a tapered portion broadening toward an aperture of a contact hole in a section in a side surface of the contact hole corresponding to the semiconductor layer and by providing the angle between the section in the side surface and the substrate surface, which is different from the angle between the rest of the section in the side surface and the substrate surface.

### EXAMPLES

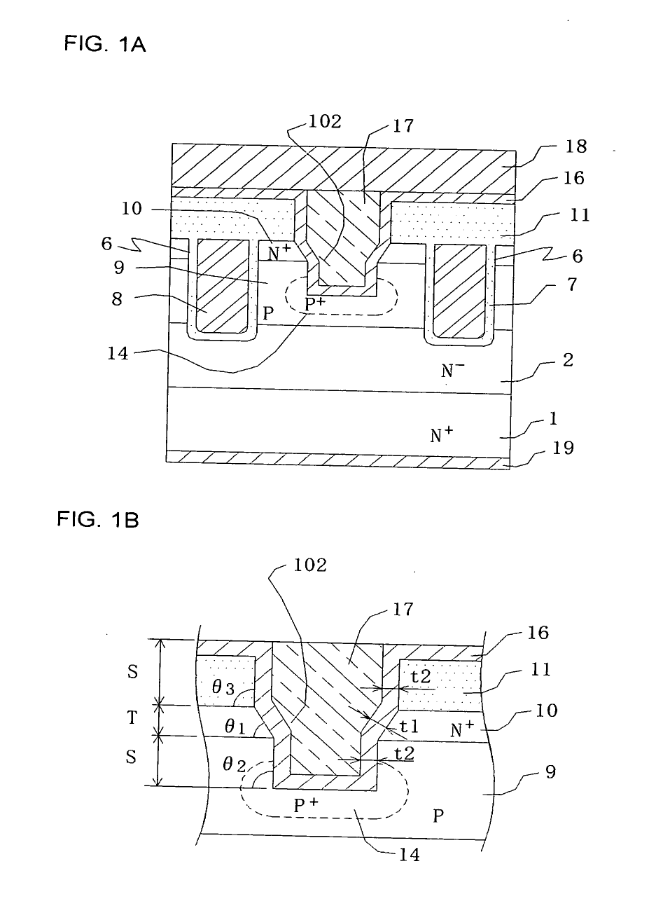

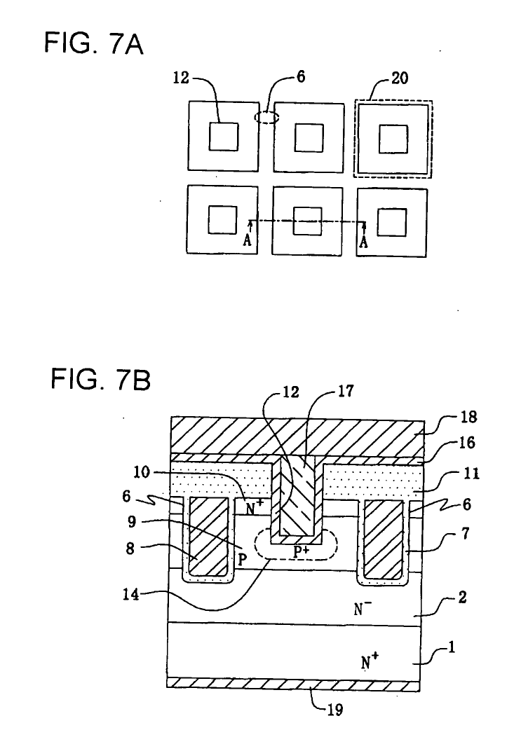

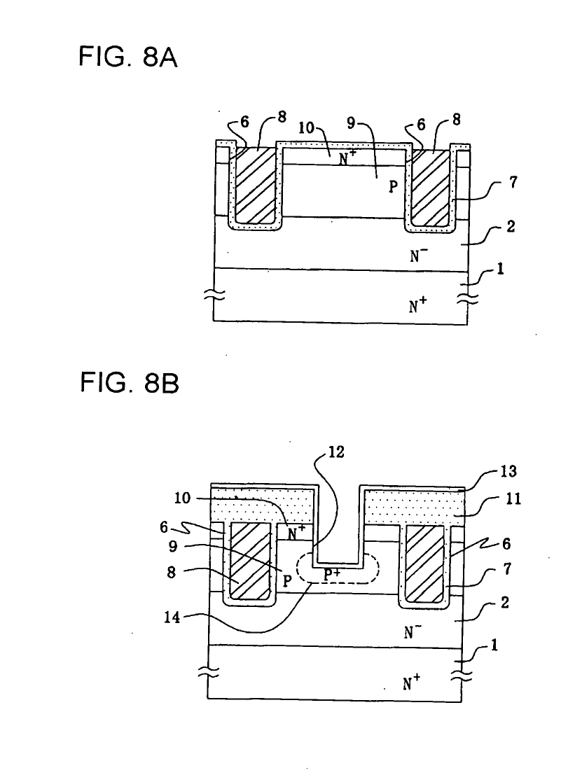

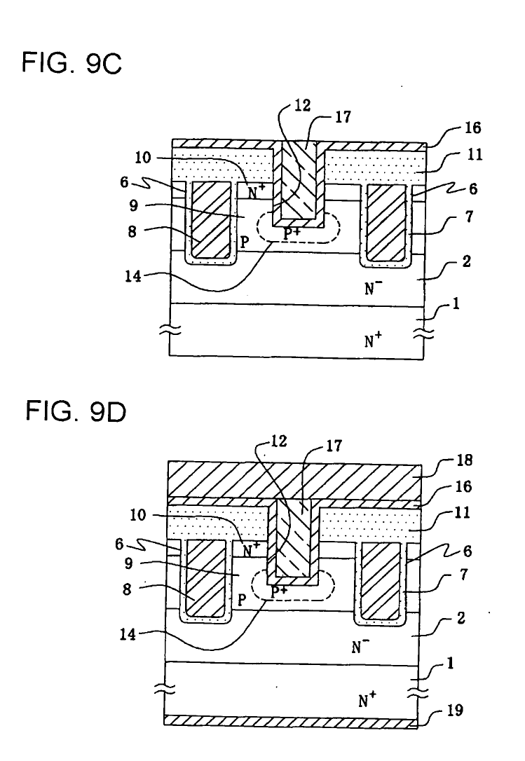

As an example of a semiconductor device according to the present invention, a UMOSFET having an electric conductor plug that couples a source layer formed on a surface of a semiconductor substrate with a source electrode formed on the semiconductor substrate is shown in FIGS. 1A and 1B. FIG. 1A is a vertical sectional view of a unit cell of the UMOSFET, and FIG. 1B is an enlarged view of a main part of the cell shown in FIG. 1A. In addition to above, an identical reference numeral is assigned to an identical element that also appears in FIGS. 7A and 7B, FIGS. 8A and 8B and FIGS. 9C and 9D. In addition, since a plan view of the unit cell is identical to FIG. 7A that represents the conventional configuration, illustration and description are not presented.

In FIGS. 1A and 1B, a reference numeral 1 represents an n⁺ type silicon substrate, 2 represents an n⁻ type epitaxial layer, 6 represents a gate trench, 7 represents a gate insulating film, 8 represents a polysilicon layer, 9 represents a p type base layer serving as a first semiconductor layer, 10 represents an n⁺ type source layer serving as a second semiconductor layer, 11 represents an interlayer insulating film, 102 represents a contact hole, 14 represents a p⁺ type base contact layer, 16 represents a barrier metal, 17 represents an electric conductor plug, 18 represents a source electrode, and 19 represents a drain electrode.

As shown in FIG. 1A, a p type base layer 9 serving as a first semiconductor layer is formed on a surface of an n⁻ type epitaxial layer 2 formed on an n⁺ type silicon substrate 1.

In addition, an n⁺ type source layer 10 as the second semiconductor layer is formed on the surface of the p type base layer 9 that serves as a principal surface of the first semiconductor layer.

In addition, a gate trench 6 extending through the n⁺ type source layer 10 and the p type base layer 9 to reach the n⁻ type epitaxial layer 2 is formed, and an interior of the gate trench 6 is filled with a polysilicon layer 8 through a gate insulating film 7. The gate trenches 6 may be connected to each other or separated from each other.

An interlayer insulating film 11 is formed on the polysilicon layer 8 that serves as a gate electrode, and a contact hole 102 having a certain depth and extending through the interlayer insulating film and the n⁺ type source layer 10 to reach the p type base layer 9 is formed between the adjacent gate trenches 6. More specifically, the contact hole 102 is composed of a contact hole provided in the n⁺ type source layer 10 and the p type base layer 9, which serves as a contact hole, and a contact hole provided in the interlayer insulating film 11, which serves as a second contact hole.

In addition to above, in order to facilitate forming a buried structure of the electric conductor plug 17, a tapered angle of a fixed gradient (the tapered angle is determined as an angle between a principal surface of the first semiconductor layer and a contact hole side surface) may be provided in a section in a side surface of the contact hole 102 corresponding to the interlayer insulating film 11 and the p type base layer 9.

Here, as shown in FIG. 1B, the section in the side surface of the contact hole 102 corresponding to the n⁺ type source layer 10 (section indicated by T) includes a tapered portion broadening toward the aperture.

A first angle θ1, which is a tapered angle thereof, is within a range presented by:

45°≦θ1≦75°,

and is a smaller tapered angle, unlikely as a second angle θ2, which is a tapered angle of a section in the side surface of contact hole 102 corresponding to the interlayer insulating film 11 and the p type base layer 9 (section indicated by S) or as a third angle θ3, which is a tapered angle of a section in the side surface of the interlayer insulating film 11. The second angle θ2 and the third angle θ3 are approximately 90°, respectively.

The purpose of providing the first angle θ1 as the tapered angle is to provide an increased dimension of the contact area between the n⁺ type source layer 10 and the barrier metal 16. In addition, the purpose is also to obtain the barrier metal 16 having a larger thickness and an improved adhesiveness when the barrier metal 16 is formed via a sputter process and via a vapor deposition process.

In addition to above, the thickness t1 of the portion T in the barrier metal 16 is about 1.2 times as the thickness t2 of the portion S in the barrier metal 16, and thus preferable.

In addition, the p⁺ type base contact layer 14 is formed under the bottom of the contact hole 102.

A barrier metal 16 composed of titanium nitride (TiN) and extending over the interlayer insulating film 11 is deposited in the contact hole 102.

In addition, an electric conductor plug 17 composed of tungsten (W) is formed in the interior of the contact hole 102, and a source electrode 18 is formed on the surface thereof.

In addition, a drain electrode 19 is formed on the back surface of the n⁺ type silicon substrate 1.

In the operation of such UMOSFET as described above, a certain voltage applied to the gate electrode (not shown) causes an inversion of the p type base layer 9 that is opposed to the side surface of the gate trench 6 to create an inverted channel region, generating a drain electric current flows.

An electric current path in ON-state passes through the source electrode 18, the electric conductor plug 17, the barrier metal 16, the n⁺ type source layer 10, the inverted channel region, the n⁻ type epitaxial layer 2, the n⁺ type silicon substrate 1 and the drain electrode 19.

Since the n⁺ type source layer 10 is in contact with the thick barrier metal 16 in the T section with better adhesiveness, problems of an increased contact resistance (on-resistance) or unstable contact resistance (on-resistance) caused by stresses generated under the condition of the heat cycle are avoidable.

In addition, since the embodiment employs the configuration, in which only the section in the side surface corresponding to the n⁺ type source layer 10 is tapered to have the first angle θ1 that is a smaller taper angle, instead of employing a configuration, in which the whole side surface is tapered to have the first angle θ1 that is a smaller tapered angle, a remarkable increase in the dimension of the aperture area of the contact hole 102 can be avoided.

Such a UMOSFET is manufactured using a method, including: forming an interlayer insulating film on a second semiconductor layer formed on a surface of a first semiconductor layer; anisotropically etching said interlayer insulating film to form an opening having a predetermined opening diameter so as to expose said second semiconductor layer in a bottom thereof; isotropically etching said second semiconductor layer to form a tapered portion in said second semiconductor layer so as to expose said first semiconductor layer in a bottom thereof; anisotropically etching said first semiconductor layer to a predetermined depth; and anisotropically etching said interlayer insulating film to expose said tapered portion.

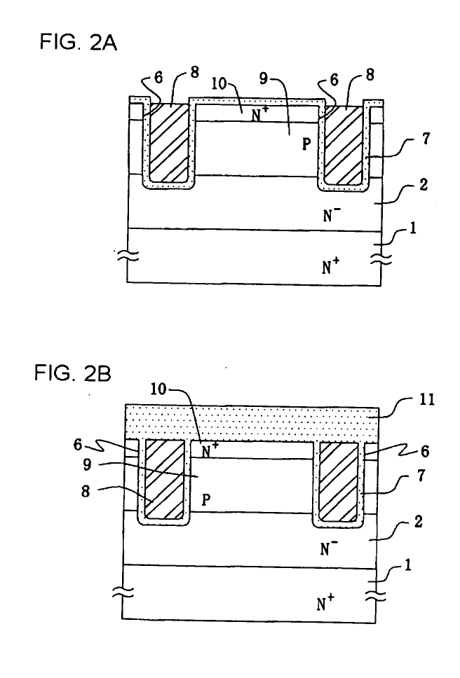

Next, a process for manufacturing the UMOSFET described above will be specifically described in reference to FIGS. 2A and 2B, FIGS. 3C and 3D, FIGS. 4E and 4F, FIGS. 5G and 5H and FIG. 6I.

FIGS. 2A and 2B, FIGS. 3C and 3D, FIGS. 4E and 4F, FIGS. 5G and 5H and FIG. 6I are cross-sectional views of a device, illustrating each operation in the manufacturing process.

First of all, as shown in FIG. 2A, an etching mask(not shown) composed of a silicon oxide film, a silicon nitride film and a silicon oxide film are formed on the n⁻ type epitaxial layer 2, which has been grown on the n⁺ type silicon substrate 1, and then a silicon etch process is conducted to form the gate trenches 6 in the n⁻ type epitaxial layer 2.

Here, the depth of the gate trench 6 is designed to be smaller than the thickness of the n⁻ type epitaxial layer 2, but larger than the thickness of a p type base layer as will be formed in the later process. In addition, a sacrificial oxide film (not shown) is grown on the silicon surface, and then is etched off to form rounded opening corners and rounded bottom corners of the gate trenches 6.

Then, the gate insulating films 7 are formed on the surface of the n⁻ type epitaxial layer 2 and in the interior of the gate trenches 6 via a thermal oxidation process, and then a polysilicon is deposited via a CVD process.

Here, for the purpose of reducing a resistance of polysilicon that serves as the gate electrode, impurity such as phosphorus (P), arsenic (As) and the like may be diffused into polysilicon after the deposition thereof, or the deposition of polysilicon may be conducted while such impurity is doped.

Next, polysilicon is etched back to form polysilicon layers 8 in the interior of the gate trenches 6, and then an ion implantation of boron (B) and a thermal processing are carried out to form a p type base layer 9 that reaches to a depth shallower than the depth of the gate trench 6.

Next, an ion implantation with arsenic (As) and a thermal processing are carried out for a certain region in the surface of the p type base layer 9 to form the n⁺ type source layer 10.

Next, as shown in FIG. 2B, an interlayer insulating film 11 is formed thereon via a CVD process.

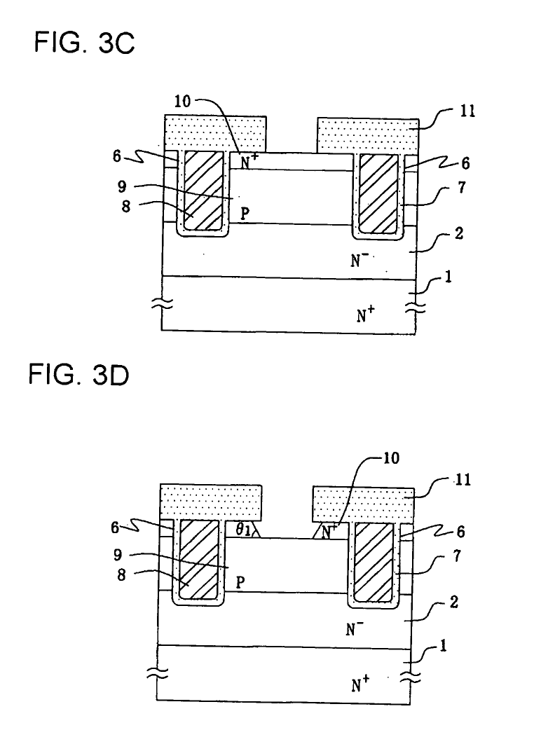

Next, as shown in FIG. 3C, a plasma etching (anisotropy etching) for the interlayer insulating film 11 is conducted through a mask of a resist mask (not shown) formed to have a certain pattern via a photolithographic process until a silicon surface is exposed, thereby forming an opening having a certain opening diameter.

Next, as shown in FIG. 3D, a wet etching (isotropic etching) process for silicon is conducted through a mask of a resist mask (not shown) and the interlayer insulating film 11 to reach the depth of the lower surface of the n⁺ type source layer 10. In addition to above, the isotropic etching may alternatively be conducted by a dry etching.

This process provides forming an undercut section in the n⁺ type source layer 10 under the interlayer insulating film 11, thereby creating a tapered portion broadening toward the aperture. Here, the first angle θ1 as the tapered angle is provided to be within a range presented by:

45°≦θ1≦75°,

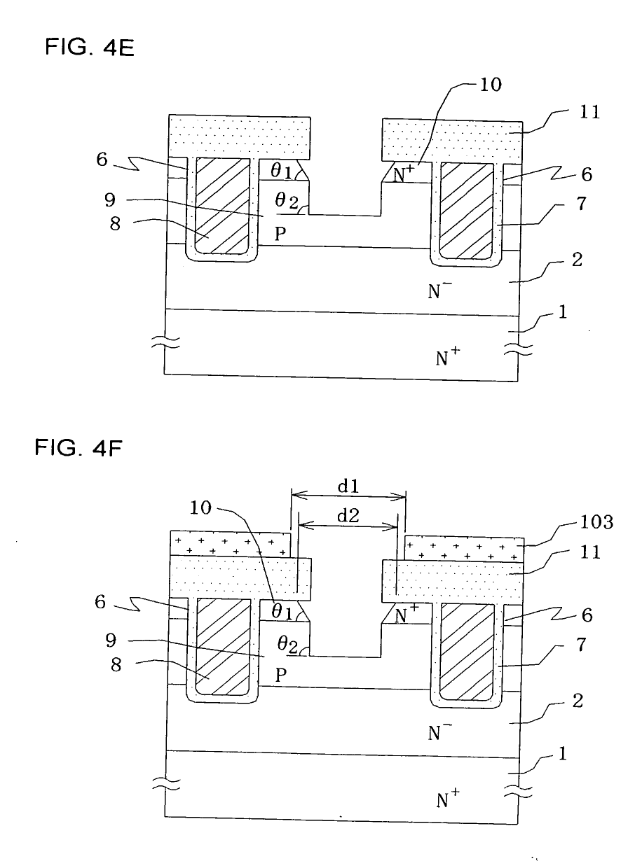

Sequentially, as shown in FIG. 4E, a plasma etching (anisotropy etching) process for the p type base layer 9 is conducted through a mask of a resist mask (not shown) and the interlayer insulating film 11 to a certain intended depth. At this time, the second angle θ2, which is the tapered angle of the side surface of the p type base layer 9, is provided to be approximately 90°.

Next, as shown in FIG. 4F, a resist mask 103 formed to have a certain pattern via a photolithographic process is formed. Here, the opening diameter d1 of the resist mask 103 is set to be slightly larger than the opening diameter d2 of the undercut section.

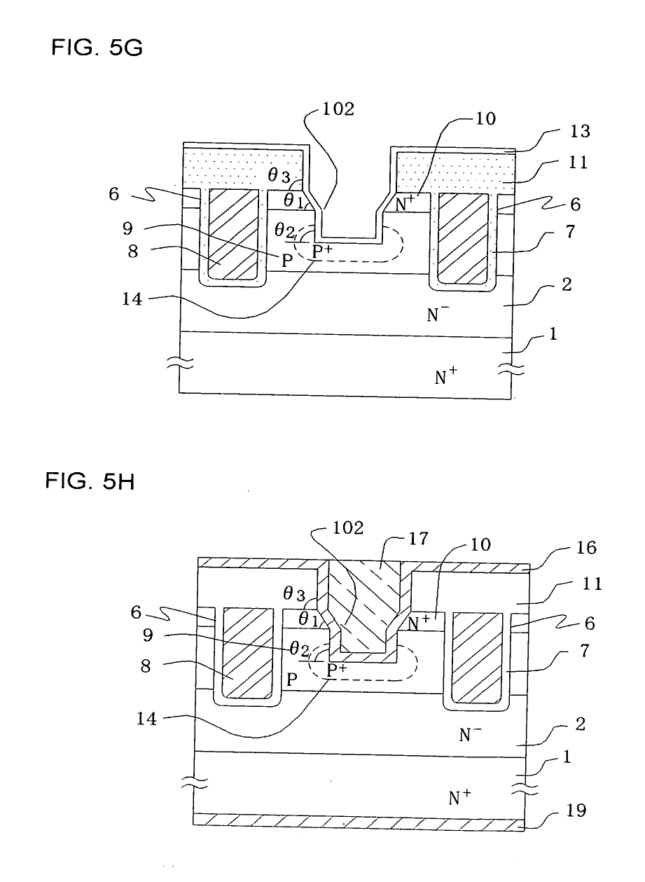

Next, as shown in FIG. 5G, visor-shaped portions in the interlayer insulating film 11 formed over the undercut section in the n⁺ type source layer 10 are removed via a plasma etching process through a mask of such resist mask. At this time, the third angle θ3, which is the tapered angle of the side surface of the interlayer insulating film 11, is provided to be approximately 90°.

Then, the resist mask is removed and an oxide film 13 is deposited via a CVD process, and thereafter, an ion implantation with BF₂ and a thermal processing are carried out to form a p⁺ type base contact layer 14 under the bottom of the contact hole 102.

Next, such oxide film 13 is removed, and then, as shown in FIG. 5H, a barrier metal 16 composed of titanium nitride (TiN) formed via a sputter process, and then tungsten (W) is deposited via a CVD process and is etched back to form an electric conductor plug 17 in the contact hole 102.

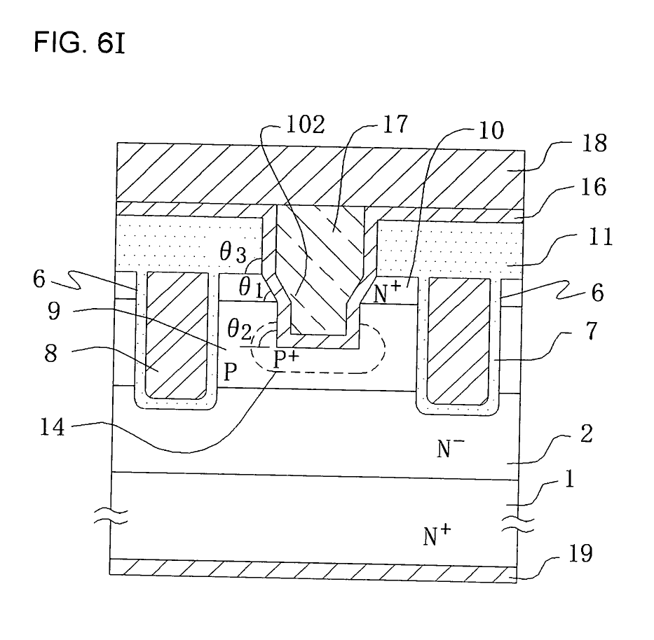

Subsequently, as shown in FIG. 6I, aluminum silicon (AlSi) is deposited thereon via a sputter process, and then a patterning is carried out via a photolithographic process and an etching process to form the source electrode 18.

Thereafter, a desired thickness of the back surface of the n⁺ silicon substrate 1 is removed, and then a vapor deposition process is conducted to form a drain electrode 19.

The above described process allows forming the contact hole 102, in which only the section in the side surface corresponding to the n⁺ type source layer 10 is tapered to have the first angle θ1, and thus is preferable.

While the above-described embodiments are illustrated in reference to the n-channel devices, the present invention may alternatively be adopted to p-channel devices.

In addition, while the above-described embodiments are illustrated in reference to the UMOSFET, the present invention is not limited thereto and is also applicable to any type of semiconductor devices provided that the device includes an electric conductor plug structure which is coupled to a semiconductor layer formed on a surface of a semiconductor substrate and an electric conductor layer formed on the semiconductor substrate in contact with the side surface of the semiconductor layer, and such configurations achieve considerable advantageous effects for the structures such as UMOSFET aimed for achieving a cell-shrinkage.

The present invention is applicable to a semiconductor device having an improved reliability and a reduced contact resistance, which is obtained by achieving an increased dimension of the contact area and an improved adhesiveness between the semiconductor layer and the barrier metal without increasing a dimension of the opening of the contact hole as low as possible.

It is apparent that the present invention is not limited to the above embodiment, and may be modified and changed without departing from the scope and spirit of the invention.

What is claimed is:

1. A semiconductor device, comprising:
a first semiconductor layer having a principal surface;
a second semiconductor layer formed on said principal surface;
a contact hole provided in said first semiconductor layer so as to extend through said second semiconductor layer; and
an electric conductor plug that plugs said contact hole,
wherein a section in a side surface of said second semiconductor layer exposed to said contact hole has a tapered portion, which broadens toward an aperture of said contact hole, and
wherein a first angle between said section in the side surface of the second semiconductor layer and said principal surface differs from a second angle between a section in a side surface of said first semiconductor layer exposed to said contact hole and said principal surface.

2. The semiconductor device as set forth in claim 1, wherein said second angle is larger than said first angle.

3. The semiconductor device as set forth in claim 2, wherein said first angle (θ1) is represented as 45°≦θ1≦75°.

4. The semiconductor device as set forth in claim 3, wherein said second angle is approximately 90°.

5. The semiconductor device as set forth in claim 1, further comprising a barrier metal formed in at least said contact hole and coupled to said first semiconductor layer and said second semiconductor layer.

6. The semiconductor device as set forth in claim 5,
wherein a thickness of said barrier metal formed on said tapered portion is larger than a thickness of the barrier metal formed on other sections in said contact hole.

7. The semiconductor device as set forth in claim 1,
wherein the cavity is a first contact hole, the semiconductor device further comprises an interlayer insulating film formed on said second semiconductor layer,
wherein a second contact hole, which is capable of exposing said first contact hole, is formed in said interlayer insulating film, and
wherein a third angle between a section in a side surface of said interlayer insulating film exposing to said second contact hole and said principal surface is larger than said first angle.

8. The semiconductor device as set forth in claim 7, wherein sections of the side surface of a contact hole that includes said first contact hole and said second contact hole has at least two inflection points where the angle with said principal surface is changed.

9. The semiconductor device as set forth in claim 8, wherein said first angle (θ1) is represented as 45°≦θ1 ≦75°,
and said second angle and said third angle are approximately 90°, respectively.

10. The semiconductor device as set forth in claim 7,
wherein said first semiconductor layer is a base layer having a second conductivity type and said second semiconductor layer is a source layer having a first conductivity type,
wherein a metal oxide semiconductor field effect transistor (MOSFET) is formed therein, said MOSFET comprising a drain layer having the first conductivity type and including said first semiconductor layer formed thereon, a gate insulating film and a gate electrode, and
wherein said electric conductor plug couples said source layer and said base layer to a source electrode formed on said interlayer insulating film.

11. The semiconductor device as set forth in claim 10,
wherein said MOSFET is a U-shaped metal oxide semiconductor field effect transistor, which further comprises a gate trench formed in portions of said source layer, said base layer and said drain layer, said gate trench including a gate insulating film and a gate electrode formed therein.
